(19) United States
(12) Patent Application Publication
(10) Pub. No.: US 2026/0255644 A1
(43) Pub. Date: Aug. 27, 2026

(54) NANO-SYNAPTIC INTEGRATED DEVICE AND PREPARATION METHOD OF SAME

(71) Applicant: SUZHOU INSTITUTE OF NANO-TECH AND NANO-BIONICS (SINANO), CHINESE ACADEMY OF SCIENCES, Suzhou (CN)

(72) Inventors: Yukun Zhao, Suzhou (CN); Shulong Lu, Suzhou (CN); Xiushuo GU, Suzhou (CN); Min Zhou, Suzhou (CN); Jianya Zhang, Suzhou (CN)

(21) Appl. No.: 18/992,486

(22) PCT Filed: Aug. 14, 2023
(86) PCT No.: PCT/CN2023/112929

§ 371 Date: Jan. 8, 2025

(30) Foreign Application Priority Data
Jul. 25, 2023 (CN) 202310916603.5

(51) Int. Cl. H10D 62/85; H10D 30/01; H10D 30/43; H10D 80/20

(52) U.S. Cl. CPC H10D 62/8503; H10D 30/014; H10D 30/43; H10D 80/251

(57) ABSTRACT

The present invention discloses a nano-synaptic integrated device and a preparation method of the nano-synaptic integrated device. The nano-synaptic integrated device includes a substrate, an insulating layer disposed on the substrate, and a plurality of nano-synaptic units disposed on the insulating layer. Each of the nano-synaptic units includes a first microelectrode and a second microelectrode disposed facing each other and a GaN-based nanowire disposed between the first microelectrode and the second microelectrode, a first end of the GaN-based nanowire is bond-connected to the first microelectrode, and a second end of the GaN-based nanowire is bond-connected to the second microelectrode. In the present invention, the GaN-based nanowire is used as a synapse element in the device. The GaN-based nanowire has a controllable direct band gap and stable physical and chemical properties. In this nano-synaptic integrated device, the plurality of nano-synaptic units are integrated and disposed on the same substrate, which can be prepared on scale, with small size and high integration level. The plurality of nano-synaptic units can be independently controlled or can be controlled in an overall array according to an arranged array pattern.

### TECHNICAL FIELD

The present invention relates to the field of artificial nerve technology, in particular to a nano-synaptic integrated device and a preparation method of the nano-synaptic integrated device.

### BACKGROUND ART

In the nervous system of the human brain, a synapse is defined as a connection point between two neurons, which serves as an important pathway for transmitting a nerve impulse from a presynaptic neuron to a postsynaptic neuron. When an electrical signal is sent to a presynaptic neuron, an electrical spike called an action potential is generated, which then releases chemicals (called neurotransmitters) across the synaptic cleft to trigger an impulse in a postsynaptic neuron. Artificial synapses imitate biological synapses in neuromorphic computing systems, and are used in various detection devices and bionic structures based on this synaptic structure.

In recent years, with the rapid development of big data, the Internet, and artificial intelligence, von Neumann architecture computing systems (independent memory and storage units) have been difficult to meet future application needs. In contrast, the human brain has a remarkable ability to process large amounts of data by simultaneously storing, integrating, and processing information through densely coordinated networks of synapses and neurons. When processing analog signals detected by sensory organs, such as visual information received by the retina, the human brain can greatly reduce energy consumption and improve data management efficiency, and the interconnected neural networks can perform distributed processing and achieve high-speed computing capabilities. Inspired by the human brain, artificial synaptic devices have emerged and attracted widespread attention for the ability to simultaneously process and store data. Therefore, artificial synapses are expected to become an indispensable core component in next-generation computing systems.

Nanowires are considered to be effective in simulating artificial synapses for learning and cognition due to outstanding properties such as large surface/volume ratio and small size. At present, the preparation of nano-synaptic devices is difficult and the integration level is extremely low. Therefore, high-density integrated systems based on nano-synaptic devices are difficult to prepare, and applications of high-density integrated systems in neuromorphic computing systems and other fields are greatly limited.

### SUMMARY OF INVENTION

In view of this, the present invention provides a nano-synaptic integrated device with a simple preparation process and a high integration level, and a preparation method of the nano-synaptic integrated device.

In order to achieve the above object, the present invention adopts the following technical solutions.

A nano-synaptic integrated device, including:
a substrate;
an insulating layer disposed on the substrate; and
a plurality of nano-synaptic units disposed on the insulating layer, in which
each of the nano-synaptic units includes a first microelectrode and a second microelectrode disposed facing each other and a GaN-based nanowire disposed between the first microelectrode and the second microelectrode, a first end of the GaN-based nanowire is bond-connected to the first microelectrode, and a second end of the GaN-based nanowire is bond-connected to the second microelectrode.

In a preferred solution, the GaN-based nanowire is a GaN nanowire, an AlGaN nanowire or an InGaN nanowire.

In a preferred solution, thicknesses of the first microelectrode and the second microelectrode are both 50 nm to 500 nm, and a distance between the first microelectrode and the second microelectrode is 0.8 μm to 5 μm.

In a preferred solution, the plurality of nano-synaptic units are arranged in an array of M rows×N columns on the insulating layer, and M and N are positive integers.

In a preferred solution, in each of the nano-synaptic units, the first microelectrode is electrically connected to a first external electrode, and the second microelectrode is electrically connected to a second external electrode. Each of the first microelectrodes of all the nano-synaptic units is connected to the first external electrode in a one-to-one correspondence, and the second microelectrodes of all the nano-synaptic units are commonly connected to the same second external electrode, or the first microelectrodes of all the nano-synaptic units are commonly connected to the same first external electrode, and the second microelectrodes of all the nano-synaptic units are commonly connected to the same second external electrode.

In a preferred solution, a first covering electrode covering the first end of the GaN-based nanowire is formed on the first microelectrode, and a second covering electrode covering the second end of the GaN-based nanowire is formed on the second microelectrode.

In a preferred solution, thicknesses of the first covering electrode and the second covering electrode are both 80 nm to 200 nm.

In a preferred solution, the first microelectrode and the first covering electrode together form a source electrode, the second microelectrode and the second covering electrode together form a drain electrode, and a gate layer is formed on a surface of the substrate opposite to the insulating layer.

Another aspect of the present invention is to provide a preparation method of the above nano-synaptic integrated device, the preparation method including:
providing the substrate and depositing the insulating layer on the substrate;
preparing a plurality of sets of the first microelectrodes and the second microelectrodes on the insulating layer using a photolithography process, each of the first microelectrodes being disposed facing a corresponding one of the second microelectrodes;
growing the GaN-based nanowire on an epitaxial substrate;
peeling the GaN-based nanowire from the epitaxial substrate and transferring the GaN-based nanowire between the first microelectrode and the second microelectrode; and
bond-connecting two ends of the GaN-based nanowire to the first microelectrode and the second microelectrode, respectively.

In a preferred solution, after the GaN-based nanowire is transferred between the first microelectrode and the second microelectrode, a dielectrophoresis process is used to make the two ends of the GaN-based nanowire overlap surfaces of the first microelectrode and the second microelectrode, respectively. Process parameters of the dielectrophoresis process include an AC voltage of 3 V to 15 V, a frequency of 1 kHz to 1 MHz, an energization time of 10 min to 20 min, and a dielectrophoresis solution of acetone, isopropyl alcohol or ethanol.

According to the nano-synaptic integrated device and the preparation method of the nano-synaptic integrated device provided by the embodiments of the present invention, the GaN-based nanowire is used as a synapse element in the device. The GaN-based nanowire has a controllable direct band gap and stable physical and chemical properties. The GaN-based nanowire is compatible with semiconductor technology in the related art, and has a mature, stable and simple preparation process. The GaN-based nanowire can integrate an optoelectronic neuromorphic device on a chip together with a light source, and can have the performance of both a light pulse stimulation and an electrical pulse stimulation. In this nano-synaptic integrated device, the plurality of nano-synaptic units are integrated and disposed on the same substrate, which can be prepared on scale, with small size and high integration level. The plurality of integrated nano-synaptic units can be configured to be independently controlled or configured to be controlled in an overall array according to an arranged array pattern.

### BRIEF DESCRIPTION OF DRAWINGS

FIG. 1 is a cross-sectional view of a nano-synaptic integrated device in a first embodiment.

FIG. 2 is a schematic diagram of a distribution structure of nano-synaptic units on an insulating layer in the first embodiment.

FIG. 3 is an SEM image of a GaN-based nanowire connected between microelectrodes in the first embodiment.

FIG. 4 is a diagram showing results of light pulse stimulation response tests with different pulse times in the first embodiment.

FIG. 5 is a diagram showing results of a continuous light pulse stimulation response test in the first embodiment.

FIG. 6 is a schematic diagram of a distribution structure of nano-synaptic units on an insulating layer in another preferred embodiment.

FIG. 7 is a schematic diagram of a distribution structure of nano-synaptic units on an insulating layer in yet another preferred embodiment.

FIG. 8 is a cross-sectional view of a nano-synaptic integrated device in a second embodiment.

FIG. 9 is a diagram showing test results of simulating synaptic learning behavior in the second embodiment.

FIG. 10 is a cross-sectional view of a nano-synaptic integrated device in a third embodiment.

### DESCRIPTION OF THE EMBODIMENTS

In order to make the object, technical solutions and advantages of the present invention clearer, specific embodiments of the present invention are described in detail below with reference to the accompanying drawings. Examples of these preferred embodiments are shown in the drawings. The embodiments of the present invention shown in and described with reference to the drawings are merely exemplary, and the present invention is not limited to these embodiments.

Here, it should also be noted that, in order to avoid obscuring the present invention due to unnecessary details, only the structures and/or processing steps closely related to the solutions according to the present invention are shown in the drawings, and other details not related to the present invention are omitted.

### First Embodiment

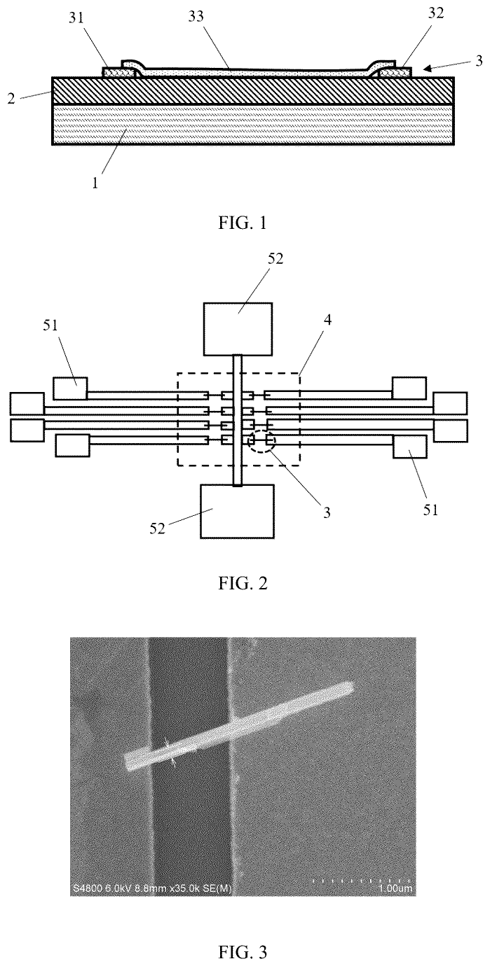

The present embodiment provides a nano-synaptic integrated device. FIG. 1 is a cross-sectional view of the nano-synaptic integrated device of the present embodiment at a position corresponding to a nano-synaptic unit, and FIG. 2 is a schematic diagram of a distribution structure of nano-synaptic units on an insulating layer in the present embodiment.

Referring to FIGS. 1 and 2, the nano-synaptic integrated device includes a substrate 1 and an insulating layer 2 disposed on the substrate 1. The insulating layer 2 is provided with a plurality of nano-synaptic units 3, and the plurality of nano-synaptic units 3 are arranged in an array to form a nano-synaptic unit array 4.

Each of the nano-synaptic units 3 includes a first microelectrode 31 and a second microelectrode 32 disposed facing each other and a GaN-based nanowire 33 disposed between the first microelectrode 31 and the second microelectrode 32. A first end of the GaN-based nanowire 33 is bond-connected to the first microelectrode 31, and a second end of the GaN-based nanowire 33 is bond-connected to the second microelectrode 32. In the present embodiment, the substrate 1 is selected as a silicon substrate, and the material of the insulating layer 2 is SiO₂.

As a preferred solution, in the present third embodiment, the GaN-based nanowire is a GaN nanowire. In some other embodiments, the GaN-based nanowire is an AlGaN nanowire or an InGaN nanowire.

As a preferred solution, in the present embodiment, thicknesses of the first microelectrode 31 and the second microelectrode 32 are both 80 nm, specifically including a Ti metal layer with a thickness of 20 nm and an Au metal layer with a thickness of 60 nm which are stacked, and a distance between the first microelectrode 31 and the second microelectrode 32 is 1 μm. In some other embodiments, both the thicknesses of the first microelectrode 31 and the second microelectrode 32 are preferably set in a range of 50 nm to 500 nm, and the distance between the first microelectrode 31 and the second microelectrode 32 is preferably set in a range of 0.8 μm to 5 μm.

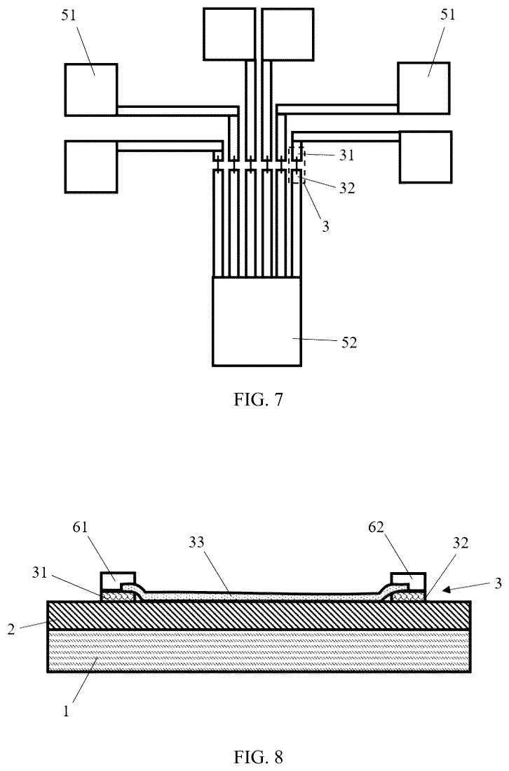

In a preferred solution, the plurality of nano-synaptic units 3 are arranged in an array of M rows×N columns on the insulating layer 2, and M and N are positive integers. As shown in FIG. 2, in the present embodiment, the plurality of nano-synaptic units 3 are arranged in an array of 4 rows×2 columns on the insulating layer 2. In some other embodiments, as shown in FIGS. 6 and 7, the plurality of nano-synaptic units 3 are arranged in an array of 6 rows×1 column on the insulating layer 2.

In a preferred solution, referring to FIG. 2, in the nano-synaptic unit 3, the first microelectrode 31 is electrically connected to a first external electrode 51, and the second microelectrode 32 is electrically connected to a second external electrode 52. In some embodiments, as shown in FIGS. 2 and 7, each of the first microelectrodes 31 of all the nano-synaptic units 3 is connected to the first external electrode 51 in a one-to-one correspondence, and the second microelectrodes 32 of all the nano-synaptic units 3 are commonly connected to the same second external electrode 52, so that each of the nano-synaptic units 3 can be independently controlled.

In some other embodiments, as shown in FIG. 6, the first microelectrodes 31 of all the nano-synaptic units 3 are commonly connected to the same first external electrode 51, and the second microelectrodes 32 of all the nano-synaptic units 3 are commonly connected to the same second external electrode 52. In this case, all the nano-synaptic units 3 need to be controlled simultaneously, that is, all the nano-synaptic units 3 may be controlled in an overall array according to an arranged array pattern.

A preparation method of the nano-synaptic integrated device provided in the present embodiment includes the following steps.

Step 1 of providing the substrate 1 and depositing the insulating layer 2 on the substrate 1.

Step 2 of preparing a plurality of sets of the first microelectrodes 31 and the second microelectrodes 32 on the insulating layer 2 using a photolithography process, each of the first microelectrodes 31 being disposed facing a corresponding one of the second microelectrodes 32.

Step 3 of growing a GaN nanowire on an epitaxial substrate using molecular beam epitaxy, transferring the GaN nanowire into an isopropyl alcohol solution through physical peeling and performing ultrasonic dispersion to fully fuse the GaN nanowire with the isopropyl alcohol solution.

Step 4 of placing the device obtained in Step 2 on a probe platform, using a micro-injector to extract 5 μL of the solution obtained in Step 3 and dropping the solution between the first microelectrode 31 and the second microelectrode 32, and making one end of the GaN nanowire in the solution overlap the first microelectrode 31 and the other end of the GaN nanowire overlap second microelectrode 32 using a dielectrophoresis method. Process parameters of the dielectrophoresis process include the following. An AC voltage can be selected from 3 V to 15 V, a frequency can be set from 1 kHz to 1 MHz, an energization time is within a range of 10 min to 20 min until the solution is completely evaporated, and the dielectrophoresis solution can be selected from acetone, isopropyl alcohol or ethanol.

Step 5 of placing the device obtained in Step 4 into an annealing furnace for high-temperature annealing so as to bond-connect the two ends of the GaN nanowire to the first microelectrode 31 and the second microelectrode 32, respectively, thereby preparing a nano-synaptic integrated device.

A surface of the obtained nano-synaptic integrated device is observed using a scanning electron microscope (SEM). As shown in FIG. 3, it can be seen that a single GaN nanowire is connected between two microelectrodes.

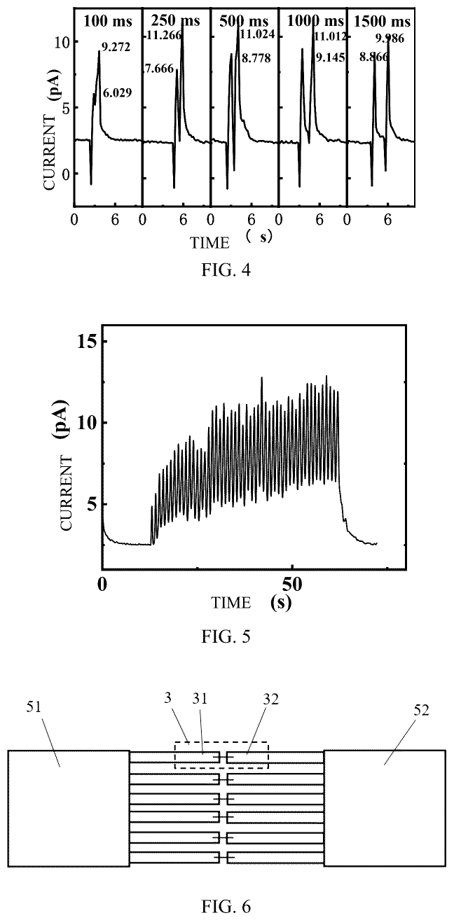

A light pulse stimulation test is conducted on the nano-synaptic integrated device obtained in the present embodiment and is specifically as follows. The first external electrode 51 and the second external electrode 52 are connected to two ends of a DC power supply, respectively, and a DC voltage of 5 V is applied to the first microelectrode 31 and the second microelectrode 32 through the first external electrode 51 and the second external electrode 52. Ultraviolet light is used to irradiate the GaN nanowire for the light pulse stimulation. (1) An output power of an ultraviolet lamp is 2 W, and a pulse time is set to 100 ms, 250 ms, 500 ms, 1000 ms and 1500 ms for a plurality of sets of tests. As shown in the test results in FIG. 4, in each set of tests, when stimulated by two light pulses, the device has a memory function for a detecting photon signal. (2) The output power of the ultraviolet lamp is 2 W and the pulse time is set to 1 s to conduct a continuous light pulse stimulation test on the GaN nanowire. As shown in the test results in FIG. 5, when there is a continuous stimulation from a signal source, the device continues to respond, and when the signal source is stopped, the device response slowly returns to an original state. It can be seen from the test results that by changing an optical power, the pulse time and the number of pulses of the ultraviolet light, synapse-like performance can be obtained, with the performance of the light pulse stimulation.

An electrical pulse stimulation test conducted on the nano-synaptic integrated device obtained in the present embodiment is specifically as follows. The first external electrode 51 and the second external electrode 52 are connected to two ends of a pulse power supply, respectively, and a pulse voltage with a voltage amplitude of 3 V and a voltage pulse time of 100 ms is applied to the first microelectrode 31 and the second microelectrode 32 through the first external electrode 51 and the second external electrode 52. It can be seen from the test results that by changing the time, the number and the voltage of the voltage pulse, synapse-like performance can be obtained, with the performance of the electrical pulse stimulation.

### Second Embodiment

A nano-synaptic integrated device provided by the present embodiment is additionally provided with the following structure based on the device structure provided by the first embodiment. Referring to FIG. 8, a first covering electrode 61 covering a first end of the GaN-based nanowire 33 is formed on the first microelectrode 31, and a second covering electrode 62 covering a second end of the GaN-based nanowire 33 is formed on the second microelectrode 32.

In the present embodiment, the first microelectrode 31 and the first covering electrode 61 together form a source electrode, and the second microelectrode 32 and the second covering electrode 62 together form a drain electrode.

In the present embodiment, thicknesses of the first covering electrode 61 and the second covering electrode 62 are both 80 nm. In some other embodiments, the thicknesses of the first covering electrode 61 and the second covering electrode 62 may be set within a range of 80 nm to 200 nm.

The difference between a preparation process of the nano-synaptic integrated device of the present embodiment and that of the first embodiment is as follows. With reference to the preparation process steps of the first embodiment, after overlapping a GaN nanowire between two microelectrodes in Step 4, the first covering electrode 61 is first prepared and formed on the first microelectrode 31 and the second covering electrode 62 is prepared and formed on the second microelectrode 32 using an overlay method, and then the annealing bonding process in Step 5 is performed.

An electrical pulse stimulation test is conducted on the nano-synaptic integrated device obtained in the present embodiment and is specifically as follows. The first external electrode 51 and the second external electrode 52 are connected to two ends of a pulse power supply, respectively, and a pulse voltage with a voltage amplitude of 5 V and a voltage pulse time of 1 s is applied to the source electrode and the drain electrode through the first external electrode 51 and the second external electrode 52. The source electrode is used to simulate the presynaptic, the drain electrode is used to simulate the postsynaptic, the pulse power supply is used to simulate a presynaptic stimulation, and the GaN nanowire is used to simulate a synaptic effect.

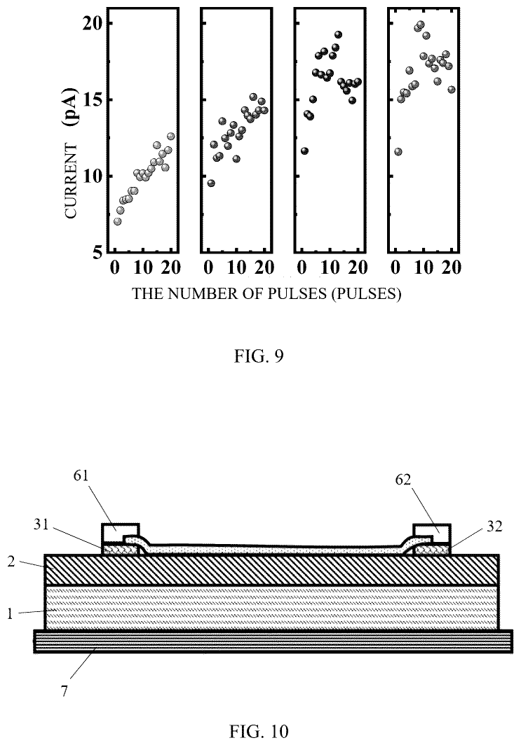

FIG. 9 is a diagram showing test results of simulating synaptic learning behavior. A total of 4 sets of tests are conducted in sequence. As shown in FIG. 9, in order from left to right, after a first set of 20 pulse stimulations is completed, an electrical stimulation is stopped for a period of time before a second set of 20 pulse stimulations is performed. After the second set of 20 pulse stimulations is completed, the electrical stimulation is stopped for a period of time before a third set of 20 pulse stimulations is performed. After the third set of 20 pulse stimulations is completed, the electrical stimulation is stopped for a period of time before a fourth set of 20 pulse stimulations is performed. Thus, a synaptic learning-forgetting-relearning process is simulated. The first 20 consecutive pulse stimulations serve as a training process of artificial synapses, which is similar to a learning process of the human brain. After the pulse stimulation is removed, a weight of the device gradually decreases, similar to a forgetting process of the human brain. After a period of time, when the pulse is applied again, only a smaller number of pulses are needed for the synaptic device to reach the amount of memory before forgetting, similar to a relearning process of the human brain. It can be seen from FIG. 9 that the nano-synaptic integrated device of the present embodiment has the performance of simulating the learning-forgetting-relearning process of synapses. This learning-forgetting-relearning process can be used in the learning and recognition functions of future artificial neural networks.

Comparing the nano-synaptic integrated device of the present embodiment with the device of the first embodiment through long-term testing, it can be seen that in the present embodiment, after the covering electrode is provided on the microelectrode, a contact point between the GaN nanowire and the electrode can be effectively protected and the reliability of the device can be improved.

### Third Embodiment

A nano-synaptic integrated device provided by the present embodiment is additionally provided with the following structure based on the device structure provided by the second embodiment. Referring to FIG. 10, a gate layer 7 is formed on a surface of the substrate 1 opposite to the insulating layer 2. In a specific solution, a PCB circuit board may be added below the substrate 1, and the PCB circuit board and the substrate 1 are connected through silver paste, so that the PCB circuit board forms a gate.

An electrical pulse stimulation test is conducted on the nano-synaptic integrated device obtained in the present embodiment and is specifically as follows. The first microelectrode 31 and the first covering electrode 61 together form a source electrode connected to one end of a pulse power supply, and the other end of the pulse power supply is connected to a lead port of the gate layer 7. The source electrode is simultaneously connected to one end of a DC power supply, and the other end of the DC power supply is connected to a drain electrode formed by the second microelectrode 32 and the second covering electrode 62. A voltage of the DC power supply is set to 10 V, a voltage of the pulse power supply is set to 5 V, and a pulse time is 1 s. The gate is used to simulate the presynaptic, the drain electrode is used to simulate the postsynaptic, the pulse power supply is used to simulate a presynaptic stimulation, the DC power supply is used to supply energy to the source electrode, and the GaN nanowire is used to simulate the paired-pulse facilitation behavior. Adding a gate in the present embodiment can make the device easier to control.

As described above, according to the nano-synaptic integrated device and the preparation method of the nano-synaptic integrated device provided by the embodiments of the present invention, the GaN-based nanowire is used as a synapse element in the device. The GaN-based nanowire has a controllable direct band gap and stable physical and chemical properties. The GaN-based nanowire is compatible with semiconductor technology in the related art, and has a mature, stable and simple preparation process. The GaN-based nanowire can integrate an optoelectronic neuromorphic device on a chip together with a light source, and can have the performance of both a light pulse stimulation and an electrical pulse stimulation. In this nano-synaptic integrated device, the plurality of nano-synaptic units are integrated and disposed on the same substrate, which can be prepared on scale, with small size and high integration level. In some specific embodiments, the plurality of integrated nano-synaptic units may be independently controlled, and in other specific embodiments, the plurality of integrated nano-synaptic units may be controlled in an overall array according to an arranged array pattern.

It should be noted that the above embodiments are merely illustrative of the technical concepts and features of the present invention. The embodiments are used to enable those skilled in the art to understand the contents of the present invention and implement the present invention accordingly, and cannot limit the protection scope of the present invention. All equivalent changes or modifications made based on the spirit of the present invention should be included in the protection scope of the present invention.

1. A nano-synaptic integrated device, comprising:
a substrate;
an insulating layer disposed on the substrate; and
a plurality of nano-synaptic units disposed on the insulating layer, wherein
each of the nano-synaptic units includes a first microelectrode and a second microelectrode disposed facing each other and a GaN-based nanowire disposed between the first microelectrode and the second microelectrode, a first end of the GaN-based nanowire is bond-connected to the first microelectrode, and a second end of the GaN-based nanowire is bond-connected to the second microelectrode.

2. The nano-synaptic integrated device according to claim 1, wherein the GaN-based nanowire is a GaN nanowire, an AIGaN nanowire or an InGaN nanowire.

3. The nano-synaptic integrated device according to claim 1, wherein thicknesses of the first microelectrode and the second microelectrode are both 50 nm to 500 nm, and a distance between the first microelectrode and the second microelectrode is 0.8 μm to 5 μm.

4. The nano-synaptic integrated device according to claim 1, wherein the plurality of nano-synaptic units are arranged in an array of M rows×N columns on the insulating layer, and M and N are positive integers.

5. The nano-synaptic integrated device according to claim 4, wherein in each of the nano-synaptic units, the first microelectrode is electrically connected to a first external electrode, and the second microelectrode is electrically connected to a second external electrode, and each of the first microelectrodes of all the nano-synaptic units is connected to the first external electrode in a one-to-one correspondence, and the second microelectrodes of all the nano-synaptic units are commonly connected to the same second external electrode, or the first microelectrodes of all the nano-synaptic units are commonly connected to the same first external electrode, and the second microelectrodes of all the nano-synaptic units are commonly connected to the same second external electrode.

6. The nano-synaptic integrated device according to claim 1, wherein a first covering electrode covering the first end of the GaN-based nanowire is formed on the first microelectrode, and a second covering electrode covering the second end of the GaN-based nanowire is formed on the second microelectrode.

7. The nano-synaptic integrated device according to claim 6, wherein thicknesses of the first covering electrode and the second covering electrode are both 80 nm to 200 nm.

8. The nano-synaptic integrated device according to claim 6, wherein the first microelectrode and the first covering electrode together form a source electrode, the second microelectrode and the second covering electrode together form a drain electrode, and a gate layer is formed on a surface of the substrate opposite to the insulating layer.

9. A preparation method of the nano-synaptic integrated device according to claim 1, the preparation method comprising:
providing the substrate and depositing the insulating layer on the substrate;
preparing a plurality of sets of the first microelectrodes and the second microelectrodes on the insulating layer using a photolithography process, each of the first microelectrodes being disposed facing a corresponding one of the second microelectrodes;
growing the GaN-based nanowire on an epitaxial substrate;
peeling the GaN-based nanowire from the epitaxial substrate and transferring the GaN-based nanowire between the first microelectrode and the second microelectrode; and
bond-connecting two ends of the GaN-based nanowire to the first microelectrode and the second microelectrode, respectively.

10. The preparation method of the nano-synaptic integrated device according to claim 9, wherein after the GaN-based nanowire is transferred between the first microelectrode and the second microelectrode, a dielectrophoresis process is used to make the two ends of the GaN-based nanowire overlap surfaces of the first microelectrode and the second microelectrode, respectively, and process parameters of the dielectrophoresis process include an AC voltage of 3 V to 15 V, a frequency of 1 kHz to 1 MHz, an energization time of 10 min to 20 min, and a dielectrophoresis solution of acetone, isopropyl alcohol or ethanol.

11. The nano-synaptic integrated device according to claim 2, wherein a first covering electrode covering the first end of the GaN-based nanowire is formed on the first microelectrode, and a second covering electrode covering the second end of the GaN-based nanowire is formed on the second microelectrode.

12. The nano-synaptic integrated device according to claim 3, wherein a first covering electrode covering the first end of the GaN-based nanowire is formed on the first microelectrode, and a second covering electrode covering the second end of the GaN-based nanowire is formed on the second microelectrode.

13. The nano-synaptic integrated device according to claim 4, wherein a first covering electrode covering the first end of the GaN-based nanowire is formed on the first microelectrode, and a second covering electrode covering the second end of the GaN-based nanowire is formed on the second microelectrode.

14. The nano-synaptic integrated device according to claim 5, wherein a first covering electrode covering the first end of the GaN-based nanowire is formed on the first microelectrode, and a second covering electrode covering the second end of the GaN-based nanowire is formed on the second microelectrode.

15. A preparation method of the nano-synaptic integrated device according to claim 2, the preparation method comprising:
providing the substrate and depositing the insulating layer on the substrate;
preparing a plurality of sets of the first microelectrodes and the second microelectrodes on the insulating layer using a photolithography process, each of the first microelectrodes being disposed facing a corresponding one of the second microelectrodes;
growing the GaN-based nanowire on an epitaxial substrate;
peeling the GaN-based nanowire from the epitaxial substrate and transferring the GaN-based nanowire between the first microelectrode and the second microelectrode; and
bond-connecting two ends of the GaN-based nanowire to the first microelectrode and the second microelectrode, respectively.

16. A preparation method of the nano-synaptic integrated device according to claim 3, the preparation method comprising:
providing the substrate and depositing the insulating layer on the substrate;
preparing a plurality of sets of the first microelectrodes and the second microelectrodes on the insulating layer using a photolithography process, each of the first microelectrodes being disposed facing a corresponding one of the second microelectrodes;
growing the GaN-based nanowire on an epitaxial substrate;
peeling the GaN-based nanowire from the epitaxial substrate and transferring the GaN-based nanowire between the first microelectrode and the second microelectrode; and
bond-connecting two ends of the GaN-based nanowire to the first microelectrode and the second microelectrode, respectively.

17. A preparation method of the nano-synaptic integrated device according to claim 4, the preparation method comprising:
providing the substrate and depositing the insulating layer on the substrate;
preparing a plurality of sets of the first microelectrodes and the second microelectrodes on the insulating layer using a photolithography process, each of the first microelectrodes being disposed facing a corresponding one of the second microelectrodes;
growing the GaN-based nanowire on an epitaxial substrate;
peeling the GaN-based nanowire from the epitaxial substrate and transferring the GaN-based nanowire between the first microelectrode and the second microelectrode; and
bond-connecting two ends of the GaN-based nanowire to the first microelectrode and the second microelectrode, respectively.

18. A preparation method of the nano-synaptic integrated device according to claim 5, the preparation method comprising:
providing the substrate and depositing the insulating layer on the substrate;
preparing a plurality of sets of the first microelectrodes and the second microelectrodes on the insulating layer using a photolithography process, each of the first microelectrodes being disposed facing a corresponding one of the second microelectrodes;
growing the GaN-based nanowire on an epitaxial substrate;
peeling the GaN-based nanowire from the epitaxial substrate and transferring the GaN-based nanowire between the first microelectrode and the second microelectrode; and
bond-connecting two ends of the GaN-based nanowire to the first microelectrode and the second microelectrode, respectively.

19. A preparation method of the nano-synaptic integrated device according to claim 6, the preparation method comprising:
providing the substrate and depositing the insulating layer on the substrate;
preparing a plurality of sets of the first microelectrodes and the second microelectrodes on the insulating layer using a photolithography process, each of the first microelectrodes being disposed facing a corresponding one of the second microelectrodes;
growing the GaN-based nanowire on an epitaxial substrate;
peeling the GaN-based nanowire from the epitaxial substrate and transferring the GaN-based nanowire between the first microelectrode and the second microelectrode; and
bond-connecting two ends of the GaN-based nanowire to the first microelectrode and the second microelectrode, respectively.

20. A preparation method of the nano-synaptic integrated device according to claim 7, the preparation method comprising:
providing the substrate and depositing the insulating layer on the substrate;
preparing a plurality of sets of the first microelectrodes and the second microelectrodes on the insulating layer using a photolithography process, each of the first microelectrodes being disposed facing a corresponding one of the second microelectrodes;
growing the GaN-based nanowire on an epitaxial substrate;
peeling the GaN-based nanowire from the epitaxial substrate and transferring the GaN-based nanowire between the first microelectrode and the second microelectrode; and
bond-connecting two ends of the GaN-based nanowire to the first microelectrode and the second microelectrode, respectively.
